(19) United States
(12) Patent Application Publication
(10) Pub. No.: US 2025/0280624 A1
(43) Pub. Date: Sep. 4, 2025

(54) SOLAR CELL AND METHOD FOR THE PRODUCTION OF A SOLAR CELL

(71) Applicant: HANWHA Q CELLS GMBH, Bitterfeld-Wolfen (DE)

(72) Inventors: Michael SCHLEY, Bitterfeld-Wolfen (DE); Bernhard KLÖTER, Bitterfeld-Wolfen (DE); Enrico JARZEMBOWSKI, Bitterfeld-Wolfen (DE)

(21) Appl. No.: 18/709,348

(22) PCT Filed: Nov. 11, 2022
(86) PCT No.: PCT/DE2022/100843

§ 371 Date: Oct. 16, 2024

(30) Foreign Application Priority Data
Nov. 11, 2021 (DE) 10 2021 129 460.6

(51) Int. Cl. H10F 77/30; H10F 77/20

(52) U.S. Cl. CPC H10F 77/311; H10F 77/219

(57) ABSTRACT

A solar cell, including: a substrate having a front side, rear side and plurality of edges extending between the front and rear sides; a conductive front-side layer on a front-side surface; an electrode on the front side electrically connected to the conductive front-side layer; a highly-doped rear-side layer on a surface of the rear side; a tunnel layer on the highly-doped rear-side layer; a conductive rear-side layer on the highly-doped rear-side layer and the tunnel layer; an electrode on the rear side electrically connected to the conductive rear-side layer; an insulation portion formed adjacent to the front-side surface and on the edges adjacent to the front-side surface. A rear-side layer assembly, including the rear-side layer, the tunnel layer and the conductive rear-side layer, is recessed in the insulation portion so that electrical contact between the highly-doped rear-side layer and the conductive front-side layer is structurally prevented.

### RELATED APPLICATIONS

The present application is a National Phase entry of PCT Application No. PCT/DE2022/100843, filed Nov. 11, 2022, which claims priority to German Patent Application No. 10 2021 129 460.6, filed Nov. 11, 2021, the disclosures of which are hereby incorporated by reference herein in their entirety.

### FIELD OF THE INVENTION

The invention relates to a solar cell and a method for the production of a solar cell. In particular, the invention relates to a solar cell comprising a substrate having a front side and a back side and a plurality of edges extending between the front side and back side, a conductive front-side layer, a front-side electrode, a tunnel layer, a conductive back-side layer, and a back-side electrode, and to a method for the production of this solar cell. The front side is the side on which light is incident during operation of the solar cell, while the back side constitutes a side of the solar cell facing away from the light during operation of the solar cell.

The conductive front-side layer is arranged on a surface of the front side, and the front-side electrode is arranged on the front side, in particular on the conductive front-side layer, and is electrically connected to the conductive front-side layer. The tunnel layer is arranged on a surface of the back side. The conductive back-side layer is arranged on the tunnel layer. The back-side electrode is arranged on the back side and electrically connected to the conductive back-side layer. Such a solar cell is referred to as a TOPCon (Tunnel Oxide Passivated Contact) cell.

### BACKGROUND OF THE INVENTION

A solar cell of this type is known from EP 3 026 713 A1, wherein the solar cell comprises an insulation portion, in which the conductive back-side layer and optionally the tunnel layer are cut out, with the result that electrical contact between the conductive back-side layer and the conductive front-side layer is structurally prevented. Said insulation portion is necessary since the layers situated on the back side are formed during the production method in such a way that they also extend along the edges and, optionally, also extend around onto the front side, i.e. are formed in regions of the front side adjacent to the edges. Said insulation portion can be arranged at a marginal region of the front side, of the edges or of the back side. There is still a need for a solar cell improved even further.

Therefore, the invention is based on the object of providing an improved solar cell and a method for the production of such a solar cell.

### SUMMARY

This object is achieved by a solar cell having the features as claimed in the claims and a method having the features as claimed in the claims. Advantageous modifications and developments are specified in the dependent claims.

The invention is based firstly on the basic concept or insight that during a process implementation for the production of a solar cell in which the substrate is provided with a tunnel layer on the back side of the substrate and then the conductive back-side layer is applied on the tunnel layer using a doping step and a subsequent annealing step, a highly doped back-side layer is formed while these process steps are carried out, with the result that the highly doped back-side layer is arranged between the substrate and the tunnel layer. Secondly, the invention is based on the insight that a short circuit (shunt) occurs in the region where the highly doped back-side layer meets the conductive front-side layer, since the tunnel layer does not offer sufficient insulation for the current flow. Therefore, the insulation portion lies on or in the vicinity of the edge of the solar cell in particular in the region in which the conductive front-side layer and the highly doped back-side layer meet. Furthermore, the meeting of the conductive back-side layer and the conductive front-side layer is likewise avoided, with the result that such a contact zone is not formed and no short circuit arises.

The invention relates to a solar cell, comprising
a substrate having a front side and a back side and a plurality of edges extending between the front side and back side,
a conductive front-side layer arranged on a surface of the front side,
a front-side electrode arranged on the front side and electrically connected to the conductive front-side layer,
a highly doped back-side layer arranged on a surface of the back side,
a tunnel layer arranged on the highly doped back-side layer,
a conductive back-side layer arranged on the highly doped back-side layer and the tunnel layer,
a back-side electrode arranged on the back side and electrically connected to the conductive back-side layer,
an insulation portion formed adjacent to the surface of the front side and on the edges adjacent to the surface of the front side, wherein a back-side layer assembly comprising the highly doped back-side layer, the tunnel layer and the conductive back-side layer is cut out in the insulation portion, with the result that electrical contact between the highly doped back-side layer and the conductive front-side layer is structurally prevented.

This solar cell comprises a highly doped back-side layer between the substrate and the tunnel layer. The insulation portion ensures that the conductive front-side layer does not have electrical contact either with the highly doped back-side layer or with the conductive back-side layer, in order to prevent a short circuit.

In one preferred embodiment, the insulation portion has a width in the range of 1 nm to 1 mm, wherein the width of the insulation portion corresponds to a distance between the conductive front-side layer and the back-side layer assembly. This width range has proved to be sufficient for ensuring that no or at least no significant short-circuit current flows when the solar cell is used as intended. In the case of the specified width, the functional feature of electrical insulation is crucial, rather than the exact structural dimension. Even a width in the nanometers range provides the required electrical insulation. The ultimately realized width of the insulation portion depends in particular on the production method chosen and on the process implementation during the production of the insulation portion.

Preferably, the solar cell furthermore comprises a front-side passivation layer arranged on the conductive front-side layer. The front-side passivation layer is preferably arranged on a side of the conductive front-side layer facing away from the substrate. Alternatively or additionally, the solar cell furthermore comprises a back-side passivation layer arranged on the tunnel layer and the conductive back-side layer. The back-side passivation layer is preferably arranged on a side of the conductive back-side layer facing away from the tunnel layer. Preferably, the front-side passivation layer and/or the back-side passivation layer are/is a dielectric layer.

The substrate is preferably a silicon wafer, more preferably an n-type c-Si wafer. The conductive front-side layer is preferably a p-type emitter layer, more preferably a p+-type emitter layer. The conductive front-side layer is preferably acceptor-doped, more preferably boron-doped. The tunnel layer is preferably a thin silicon oxide layer in the form of SiOx where 0<x<=2. In one preferred embodiment, the conductive back-side layer is formed as an n-type emitter layer, preferably as an n-type poly-Si layer. The conductive back-side layer is preferably donor-doped, in particular phosphorus-doped. The highly doped back-side layer is preferably an n-doped region, more preferably n+-doped region, which is formed as a layer. Without wishing to be tied to the following hypothesis, it is assumed that the highly doped back-side layer arises during the production of the conductive back-side layer in the course of the doping and annealing steps by way of indiffusion of the dopant through the tunnel layer into the substrate.

Furthermore, the invention relates to a method for the production of a solar cell, comprising the following steps
providing a solar cell semifinished product, wherein the solar cell semifinished product comprises:
   a substrate having a front side and a back side and a plurality of edges extending between the front side and back side,
   a conductive front-side layer arranged on a surface of the front side,
   a front-side glass layer arranged on the conductive front-side layer,
   a highly doped back-side layer arranged on a surface of the back side and extending along the edges to the front side,
   a tunnel layer arranged on the highly doped back-side layer and also extending along the edges to the front side,
   a conductive back-side layer arranged on a side of the tunnel layer facing away from the highly doped back-side layer, and extending along the edges to the front side,
   a back-side glass layer arranged on a side of the conductive back-side layer facing away from the tunnel layer, and
carrying out edge insulation, with the result that an insulation portion is formed on a surface of the front side adjacent to the edges, wherein a back-side layer assembly comprising the highly doped back-side layer, the tunnel layer and the conductive back-side layer is cut out in the insulation portion, with the result that electrical contact between the back-side layer assembly and the conductive front-side layer is structurally prevented.

The advantages and modifications described with respect to the solar cell apply, mutatis mutandis, to the method, and vice versa.

The edge insulation provided prevents significant short-circuit currents from being able to flow from the conductive front-side layer into the highly doped back-side layer and into the conductive back-side layer. The electrical isolation of these layers therefore sufficiently prevents such short-circuit currents during operation of the solar cell.

The highly doped back-side layer is preferably formed during the production of the conductive back-side layer, which is produced by means of applying, doping and annealing the back-side layer, by means of indiffusion into the substrate. The annealing is preferably carried out at a temperature of 800-1100° C. By virtue of this process implementation, in the case of a substrate already provided with the conductive front-side layer, the conductivity thereof resulting in particular from doping, the highly doped back-side layer is also formed at the edges, with the result that an intermediate region arises in which the doping of the conductive front-side layer and the doping of the highly doped back-side layer meet and form the intermediate region. The process implementation is preferably configured for the production of the solar cell semifinished product in such a way that said intermediate region is formed at the front side adjacent to the edges in order to implement the edge insulation at the front side and optionally at the edges in such a way that the insulation portion is formed on a surface of the front side adjacent to the edges and is formed in the intermediate region.

In one preferred embodiment, the edge insulation comprises carrying out a front-side acidic etching step and subsequently carrying out an alkaline etching step. As a result of the front-side acidic etching step, in particular the back-side glass layer situated there is removed, while it is maintained on the back side. The front-side acidic etching step is preferably carried out inline. The complete removal of the back-side glass layer from the front side is very important since the conductive back-side layer, the tunnel oxide and the parts of the highly doped back-side layer on the front side and the edges are removed in the subsequent alkaline etching step. What is of significance is that a purely alkaline etching step does not suffice to remove the back-side glass layer since the latter acts like an etch stop in the alkaline etching process. The alkaline etching step can optionally be carried out as a single-side process (batch or inline) or as an immersion process (batch). The front-side glass layer is at least partly maintained in the course of the front-side acidic etching step. This is able to be realized by way of a partial oxide etch or thinning of the front-side glass layer. The layer thicknesses of the back-side glass layer and the front-side glass layer are formed accordingly.

Preferably, the acidic etching step comprises exposing the front side to an HF-containing solution. The back-side glass layer is thereby effectively removed on the front side. More preferably, the acidic etching step comprises exposing the front side to an HF-containing solution which contains 1-10% by weight HF, at 10-40° C. and for 10 s to 100 s. This process implementation ensures that the back-side glass layer is completely removed in the region exposed to the HF-containing solution, without the back-side glass layer on the back side being damaged, since the latter is still required as protection of the back side in the alkaline etching step. It is additionally ensured that the thickness of the front-side glass layer is not reduced too much, since the latter is required as protection of the front side in the alkaline etching step. Characteristics of this acidic etching step are that the exposed conductive back-side layer is hydrophobic, while the back-side and front-side glass layers are hydrophilic. By virtue of the local residues of the back-side glass layer on the back side, in the subsequent alkaline etching step on the back side it is possible to produce a water cap which protects the conductive back-side layer on the back side against being removed since, in this step, the intention is to remove the conductive back-side layer, the tunnel oxide and the parts of the highly doped back-side layer on the front side and the edges.

Preferably, the alkaline etching step is carried out wet-chemically. In one preferred embodiment, the alkaline etching step comprises exposing the front side and optionally the back side to a KOH-containing solution. More preferably, the alkaline etching step comprises exposing the front side and optionally the back side to a KOH-containing solution which contains 1-20% by weight KOH, preferably 5-20% by weight KOH, at 50-85° C. and for 50-200 s. This ensures that the conductive back-side layer is completely removed from the front side and optionally from the edges. The removal of the conductive back-side layer on the front side is visible using a microscope, for example. The thickness of the front-side glass layer, too, can be reduced by the alkaline etching step, which is perceptible by way of a color change.

If the alkaline etching step is carried out for long enough to remove the tunnel layer and the highly doped back-side layer in the insulation portion, a solar cell is provided whose front side and back side have neither the front-side glass layer nor the back-side glass layer, respectively. These can be removed by acidic etching, preferably wet-chemically by exposing the front and back sides to an HF-containing solution. One characteristic of this process implementation is that the wafer surfaces are hydrophobic after removal of the glass layers. Besides the removal of the glass layers, the surfaces can be cleaned of residues by the acidic etching. After the acidic etching, the front side and back side can each be provided with passivation layers and electrodes. Methods for this purpose are generally known.

If the alkaline etching step is terminated after removal of the conductive back-side layer from the front side and edges, with the result that the tunnel layer and the highly doped back-side layer are completely maintained on the front side and the edges, the possibility of short circuit still exists in the vicinity of the edge. Preferably, in this case, the edge insulation furthermore comprises, after the alkaline etching step, carrying out a further acidic etching step and after that carrying out a further alkaline etching step. The further treatment removes the tunnel layer and the highly doped back-side layer from the front side and at the edges as well, with the result that contact between the conductive front-side layer and the back-side layer assembly is interrupted and the short circuit is thus removed. The tunnel layer is removed by the further acidic etching step, and the highly doped back-side layer is removed by the subsequent further alkaline etching step. Afterwards, preferably, the front-side glass layer and the back-side glass layer still situated on the back side are removed by the acidic etching, as already described above. After the acidic etching, once again the solar cell is provided whose front side and back side can each be provided with passivation layers and electrodes.

In one preferred embodiment, the further acidic etching step comprises exposing the front side to an HF-containing solution and the further alkaline etching step comprises exposing the front side and optionally the back side to a KOH-containing solution, more preferably exposing the front side and optionally the back side to a KOH-containing solution which contains 5-20% by weight KOH, at 50-85° C. and for 50-200 s. These process parameters ensure complete removal of the tunnel layer and/or the highly doped back-side layer. The further alkaline etching step can optionally be carried out as a single-side process (batch or inline) or as an immersion process (batch).

Preferably, in a first method variant, the edge insulation comprises two method steps, namely the acidic etching and the subsequent alkaline etching, as described above. Alternatively, in a second method variant, the edge insulation comprises four method steps, namely the acidic etching, the subsequent alkaline etching, a subsequent further acidic etching and a subsequent alkaline etching, as described above. The first method variant is preferred over the second method variant.

The edge insulation can be implemented in such a way that the etchings only etch away the relevant layers, as described above, in the intermediate region or alternatively etch away the relevant layers additionally at the edges. The result ultimately depends on the process implementation.

After the first or second method variant, the front-side glass layer from the front side and the back-side glass layer from the back side are preferably subjected to an acidic etching on both sides, in which the front-side glass layer and the back-side residues of the back-side glass layer are removed.

In one preferred embodiment, the conductive back-side layer is formed as an n-type emitter layer, more preferably an n+-type emitter layer, preferably as an n-type poly-Si layer. The conductive back-side layer is preferably doped with phosphorus. The back-side glass layer is preferably a phosphosilicate glass layer or a silicon oxide layer in the form of SiOx where 0<x<=2.

Preferably, the conductive front-side layer is formed as a p-type emitter layer, more preferably as a p+-type emitter layer. Preferably, the conductive front-side layer is boron-doped. The front-side glass layer is preferably a borosilicate glass layer or a silicon oxide layer in the form of SiOx where 0<x<=2.

### BRIEF DESCRIPTION OF THE DRAWINGS

The invention will be elucidated below on the basis of exemplary embodiments with reference to the figures. In the figures here, in each case schematically and not to scale:

FIGS. 1 and 2 each show a method step in a method for the production of a solar cell in accordance with the prior art; and

FIGS. 3 to 6 each show a method step in a method for the production of a solar cell in accordance with the present invention.

### DETAILED DESCRIPTION

All of the figures each show a partial cross-sectional view of the solar cell or of a solar cell semifinished product.

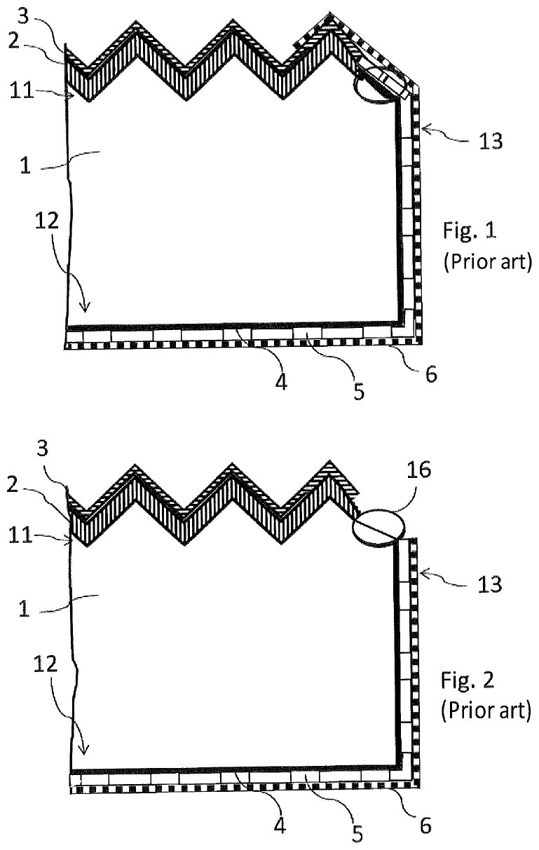

FIGS. 1 and 2 each show a method step in a method for the production of a solar cell in accordance with EP 3 026 713 A1 as prior art.

FIG. 1 shows provision of a solar cell semifinished product comprising a substrate 1 having a front side 11 and a back side 12 and a plurality of edges 13 extending between the front side 11 and back side 12, one of which edges is shown. Furthermore, a conductive front-side layer 2 is arranged on a surface of the front side 11. A front-side glass layer 3 is furthermore arranged on a side of the conductive front-side layer 2 facing away from the substrate 1. On the back side 12, a tunnel layer 4 is arranged on the substrate and also extends along the edges 13 to the front side 11. Furthermore, a conductive back-side layer 5 is arranged on a side of the tunnel layer 4 facing away from the substrate 1, and extends along the edges 13 to the front side 11. Furthermore, a back-side glass layer 6 is arranged on a side of the conductive back-side layer 5 facing away from the tunnel layer 4, and extends along the edges 13 to the front side 11.

The tunnel layer 4, the conductive back-side layer 5 and the back-side glass layer 6 extend around onto the front side 11, i.e. they are arranged in a marginal region thereof. A region in which the conductive front-side layer 2, the tunnel layer 4 and the conductive back-side layer 5 meet is highlighted by a circle. The solar cell semifinished substrate shown in FIG. 1 is subjected to a removal process, with the result that the solar cell semifinished product shown in FIG. 2 is obtained. The solar cell semifinished product shown in FIG. 2 corresponds to the solar cell semifinished product shown in FIG. 1 with the difference that it comprises an insulation portion 16 in the region highlighted by the circle and that the back-side glass layer 6 is removed. The tunnel layer 4 and the conductive back-side layer 5 are removed in the insulation portion. The removal process thus led to the removal of the back-side glass layer 6 and, in the insulation portion 16, the removal of the tunnel layer 4 and the conductive back-side layer 5.

FIGS. 3 to 6 each show a method step in a method for the production of a solar cell in accordance with the present invention.

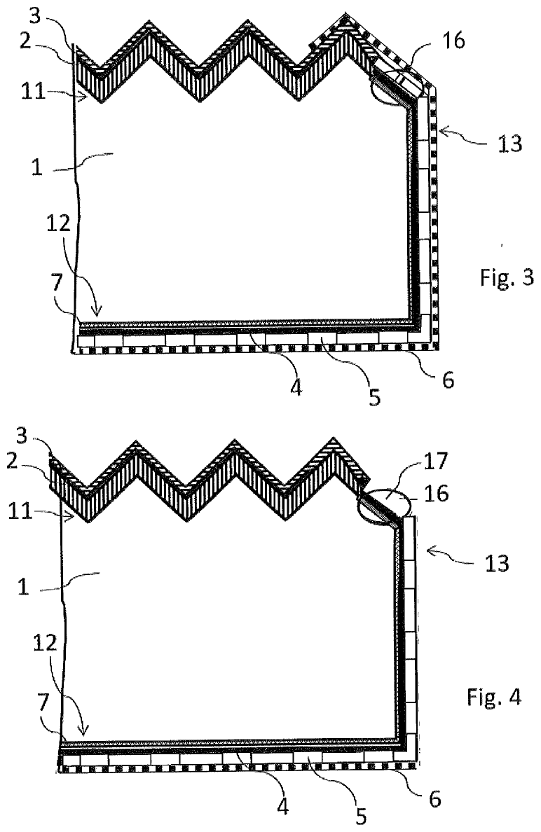

In FIG. 3, a solar cell semifinished product is provided. The solar cell semifinished product shown in FIG. 3 corresponds to the solar cell semifinished product shown in FIG. 1 with the difference that a highly doped back-side layer 7 is arranged on the back side 12 between the substrate 1 and the tunnel layer 4. The solar cell semifinished product shown in FIG. 3 is subjected to a single-side front-side acidic etching step and a single-side alkaline etching step. The solar cell semifinished product that has been subjected to the etching step is shown in FIG. 4. It corresponds to the solar cell semifinished product shown in FIG. 3 with the difference that the back-side glass layer 6 is removed in the region of the front side 11 and in the region of the edges 13 by means of the acidic etching step, such that it remains only on the back side 12, with the difference that an insulation portion 16 is formed by the alkaline etching step. The conductive back-side layer 5 is removed in the insulation portion 16, with the result that an intermediate region 17 is exposed in which the conductive front-side layer 2 meets the tunnel layer 4 and the highly doped back-side layer 7. The solar cell semifinished product shown in FIG. 4 is either furthermore subjected to the aforementioned alkaline etching step or alternatively subjected to a further single-side front-side acidic etching step and a further alkaline etching step.

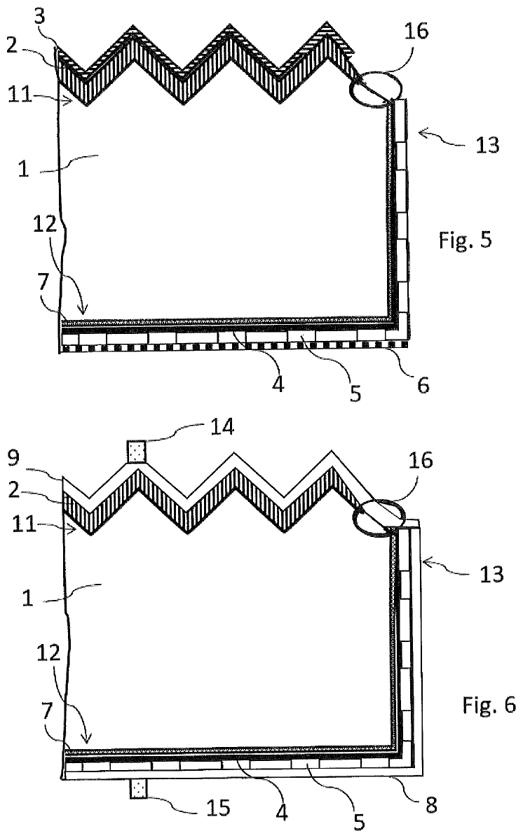

In a first method variant, proceeding from the solar cell semifinished product shown in FIG. 3, firstly an acidic etching is performed, which etches away the back-side glass layer 6 at the front side 11 and the edges 13, and then an alkaline etching is performed, which etches away the conductive back-side layer 5, the tunnel layer 4 and the highly doped back-side layer 7 in the intermediate region 17 and thereby forms the insulation portion 16. In this way, after applying the acidic etching and subsequently the alkaline etching to the solar cell semifinished product shown in FIG. 3, the solar cell semifinished product shown in FIG. 5 is obtained directly. By contrast, if the alkaline etching step is terminated before the tunnel layer 4 and the highly doped back-side layer 7 are etched away, the solar cell semifinished product shown in FIG. 4 is obtained after the acidic etching and subsequent alkaline etching. In a second method variant, this solar cell semifinished product is then subjected to a further acidic etching, in which the tunnel layer 4 is removed, and a further alkaline etching, in which the highly doped back-side layer 7 is removed, with the result that the solar cell semifinished product shown in FIG. 5 is obtained only proceeding from the solar cell semifinished product shown in FIG. 4, after the further acidic and alkaline etchings.

In summary, proceeding from the solar cell semifinished product shown in FIG. 3, the solar cell semifinished product shown in FIG. 5 can be obtained by way of two method steps in the first method variant, namely the acidic etching and the subsequent alkaline etching, and by way of four method steps in the second method variant, the acidic etching and the subsequent alkaline etching, followed by a further acidic etching and a final alkaline etching.

A solar cell semifinished product shown in FIG. 5 is obtained after one of the two aforementioned method variants has been carried out. It corresponds to the solar cell semifinished product shown in FIG. 4 with the difference that the insulation portion 16 is free of the tunnel layer 4 and the highly doped back-side layer 7. The tunnel layer 4, the highly doped back-side layer 7 and also the intermediate region 17 are removed in the insulation portion 16. The solar cell semifinished product shown in FIG. 5 is then subjected to an acidic etching on both sides, in which the front-side glass layer 3 and the back-side residues of the back-side glass layer 6 are removed, with the result that the front side 11 can be provided with a front-side passivation layer 9 and a front-side electrode 14, which is electrically contacted with the conductive front-side layer 2. The back side 12, too, can furthermore be provided with a back-side passivation layer 8 applied to the conductive back-side layer 5, and with a back-side electrode 15, which are electrically connected to the conductive back-side layer 5. Such a solar cell provided with the aforementioned passivation layers 8, 9 and electrodes 14, 15 is shown in FIG. 6.

The solar cell semifinished products shown in FIGS. 3, 4, 5 and the solar cell shown in FIG. 6 are each illustrated so that the conductive back-side layer 5, the tunnel layer 4 and the highly doped back-side layer 7 are in each case present at the edges 13. However, all these layers can also be removed along relatively large portions or the entire edges 13 during the edge insulation by means of the etchings carried out, depending on the process implementation.

### LIST OF REFERENCE SIGNS

1 substrate
2 conductive front-side layer
3 front-side glass layer
4 tunnel layer
5 conductive back-side layer
6 back-side glass layer
7 highly doped back-side layer
8 back-side passivation layer
9 front-side passivation layer
11 front side
12 back side
13 edge
14 front-side electrode
15 back-side electrode
16 insulation portion
17 intermediate region

1. A solar cell, comprising:
a substrate having a front side, a back side and a plurality of edges extending between the front side and the back side,
a conductive front-side layer arranged on a surface of the front side,
a front-side electrode arranged on the front side and electrically connected to the conductive front-side layer,
a highly-doped back-side layer arranged on a surface of the back side,
a tunnel layer arranged on the highly-doped back-side layer,
a conductive back-side layer arranged on the highly-doped back-side layer and the tunnel layer,
a back-side electrode arranged on the back side and electrically connected to the conductive back-side layer,
an insulation portion formed adjacent to the surface of the front side and on the edges adjacent to the surface of the front side, wherein a back-side layer assembly comprising the highly-doped back-side layer, the tunnel layer and the conductive back-side layer is cut out in the insulation portion, such that electrical contact between the highly-doped back-side layer and the conductive front-side layer is structurally prevented.

2. The solar cell as claimed in claim 1, wherein the insulation portion has a width in a range of 1 nm to 1 mm, and wherein the width of the insulation portion corresponds to a distance between the conductive front-side layer and the back-side layer assembly.

3. The solar cell as claimed in claim 1, wherein the solar cell furthermore comprises:
a front-side passivation layer arranged on a side of the conductive front-side layer facing away from the substrate, and/or
a back-side passivation layer arranged on a side of the conductive back-side layer facing away from the tunnel layer.

4. A method for production of a solar cell, comprising the following steps:
providing a solar cell semifinished product, wherein the solar cell semifinished product comprises:
a substrate having a front side, a back side and a plurality of edges extending between the front side and back side,
a conductive front-side layer arranged on a surface of the front side,
a front-side glass layer arranged on a side of the conductive front-side layer facing away from the substrate,
a highly-doped back-side layer arranged on a surface of the back side and extending along the edges to the front side,
a tunnel layer arranged on a side of the highly-doped back-side layer facing away from the substrate, and also extending along the edges to the front side,
a conductive back-side layer arranged on a side of the tunnel layer facing away from the highly-doped back-side layer, and extending along the edges to the front side,
a back-side glass layer arranged on a side of the conductive back-side layer facing away from the tunnel layer, and
carrying out edge insulation, such that an insulation portion is formed on a surface of the front side adjacent to the edges, wherein a back-side layer assembly comprising the highly-doped back-side layer, the tunnel layer and the conductive back-side layer is cut out in the insulation portion, such that electrical contact between the back-side layer assembly and the conductive front-side layer is structurally prevented.

5. The method as claimed in claim 4, wherein carrying out edge insulation comprises carrying out a front-side acidic etching step and subsequently carrying out an alkaline etching step.

6. The method as claimed in claim 5, wherein the acidic etching step comprises exposing the front side to an HF-containing solution.

7. The method as claimed in claim 5, wherein the alkaline etching step comprises exposing the front side to a KOH-containing solution.

8. The method as claimed in claim 5, wherein the edge insulation furthermore comprises, after the alkaline etching step, carrying out a further acidic etching step and after that carrying out a further alkaline etching step.

9. The method as claimed in claim 8, wherein the further acidic etching step comprises exposing the front side to an HF/HCl solution and the further alkaline etching step comprises exposing the front side to a KOH-containing solution.

10. The solar cell as claimed in claim 1, wherein the conductive back-side layer is formed as an n-type emitter layer and the conductive front-side layer is formed as a p-type emitter layer.

11. The method as claimed in claim 6, wherein exposing the front side to an HF-containing solution comprises exposing the front side to an HF-containing solution which contains 1-10% by weight HF, at 10-40° C. and for 10 s to 100 s.

12. The method as claimed in claim 7, wherein exposing the front side to a KOH-containing solution comprises exposing the front side to a KOH-containing solution that contains 5-20% by weight KOH, at 50-85° C. and for 50-200 s.

13. The method as claimed in claim 7, wherein the alkaline etching step comprises exposing the front side and the back side to a KOH-containing solution.

14. The method as claimed in claim 13, wherein exposing the front side and the back side to a KOH-containing solution comprises exposing the front side and the back side to a KOH-containing solution that contains 5-20% by weight KOH, at 50-85° C. and for 50-200 s.

15. The method as claimed in claim 9, wherein exposing the front side to a KOH-containing solution comprises exposing the front side to a KOH-containing solution which contains 5-20% by weight KOH, at 50-85° C. and for 50-200 s.

16. The method as claimed in claim 9, wherein the further alkaline etching step comprises exposing the front side and the back side to a KOH-containing solution.

17. The method as claimed in claim 16, wherein exposing the front side and the back side to a KOH-containing solution comprises exposing the front side and the back side to a KOH-containing solution which contains 5-20% by weight KOH, at 50-85° C. and for 50-200 s.

18. The solar cell as claimed in claim 10 wherein n-type emitter layer is an n-type poly-Si layer.

19. The solar cell as claimed in claim 4, wherein the conductive back-side layer is formed as an n-type emitter layer, and the conductive front-side layer is formed as a p-type emitter layer.

20. The solar cell as claimed in claim 19, wherein the n-type emitter layer, is an n-type poly-Si layer.
